(19) United States
(12) Patent Application Publication
(10) Pub. No.: US 2026/0344310 A1
(43) Pub. Date: Oct. 29, 2026

(54) PLANARIZATION PROCESS WITH LASER TREATMENT

(71) Applicant: Taiwan Semiconductor Manufacturing Co., Ltd., Hsinchu (TW)

(72) Inventors: Jhih Guang Wu, Kaohsiung (TW); Chih Hung Chen, Hsinchu (TW); Jin-Hao Jhang, Chubei (TW)

(21) Appl. No.: 19/737,097

(22) Filed: Jul. 10, 2026

Related U.S. Application Data
(63) Continuation of application No. 19/073,355, filed on Mar. 7, 2025.
(60) Provisional application No. 63/715,023, filed on Nov. 1, 2024.

(51) Int. Cl. H10P 14/60; H10D 30/01; H10P 14/20; H10P 52/40; H10P 95/00

(52) U.S. Cl. CPC H10P 14/6542; H10D 30/0191; H10P 14/3411; H10P 14/38; H10P 52/402; H10P 95/062

(57) ABSTRACT

A method includes forming a first layer over a second layer; performing a laser treatment process on the first layer, wherein the laser treatment process includes directing a laser beam into the first layer, wherein the laser beam modifies the first layer; and after performing the laser treatment process on the first layer, performing a planarization process on the first layer to remove the first layer, wherein the planarization process exposes the second layer.

### PRIORITY CLAIM AND CROSS-REFERENCE

This application is a continuation of U.S. patent application Ser. No. 19/073,355, filed on Mar. 7, 2025, which claims the benefit of the following provisionally filed U.S. Patent application: Application No. 63/715,023, filed on Nov. 1, 2024, each application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. During the formation of higher-density semiconductor devices, uneven topography of layers can affect yield and device performance. Thus, improved techniques to improve the planarity of layers are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, and 6 illustrate intermediate stages in the performing of a planarization process including a laser treatment process, in accordance with some embodiments.

FIGS. 7, 8, 9, and 10 illustrate intermediate stages in the performing of a planarization process including a laser treatment process, in accordance with some embodiments.

FIG. 11 illustrates a three-dimensional view of example Complementary Field-Effect Transistors (CFETs), in accordance with some embodiments.

FIGS. 12, 13, 14, 15, 16, 17, 18, 19, 20, 21, 22, 23, 24, 25, 26, and 27 are various views of intermediate stages in the manufacturing of CFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various representative embodiments are described with respect to performing a planarization process to remove material or to planarize the surface of a layer. The embodiments described herein include a laser treatment process performed on the material prior to removal by the planarization process. The laser treatment process modifies the material, allowing the material to be more easily removed by the planarization process. This can allow for more accurate material removal and can allow for improved planarity of the resulting planarized surface. For example, performing a laser treatment process can reduce the effects of initial surface topography on the planarization process, allowing for improved uniformity, reduced dishing, and improved flatness of the resulting planarized surface. The embodiments described herein are intended as illustrative and non-limiting examples, and all suitable variations, materials, applications, manufacturing steps, devices, or structures are considered within the scope of the present disclosure.

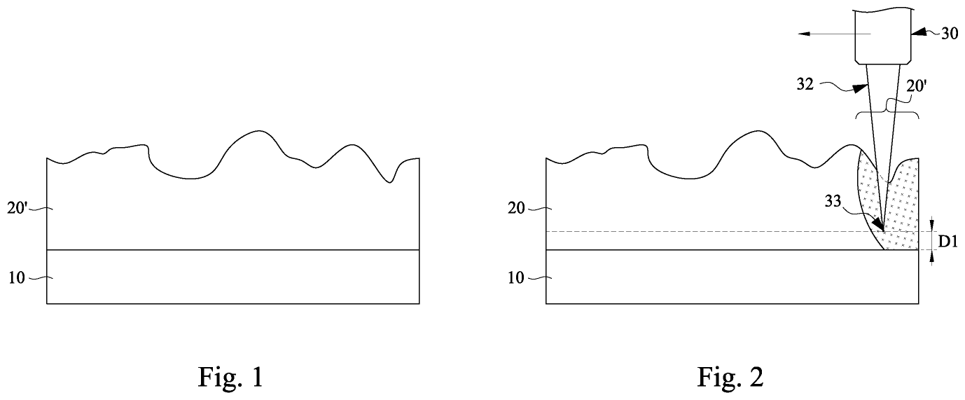

FIGS. 1 through 6 illustrate intermediate steps in a planarization process including a laser treatment process, in accordance with some embodiments. FIG. 1 illustrates a cross-sectional view of an upper layer 20 over a lower layer 10, in accordance with some embodiments. The subsequently performed planarization process removes the upper layer 20 to expose the lower layer 10. As shown in FIG. 1, the upper layer 20 has an uneven top surface. For example, the top surface of the upper layer 20 may have an uneven topography that includes roughness, bumps, dishing, recesses, or any other deviations from planarity. The lower layer 10 and the upper layer 20 may be any suitable materials, such as silicon or other semiconductor materials, oxides (e.g., silicon oxide or the like), nitrides (e.g., silicon nitride or the like), polymers, encapsulants, prepreg materials, other dielectric materials, or other suitable materials or combinations of materials. The lower layer 10 or the upper layer 20 may include multiple materials or multiple features. The lower layer 10 or upper layer 20 may be, for example, a wafer or other suitable substrate. All suitable layers or materials are considered within the scope of the present disclosure.

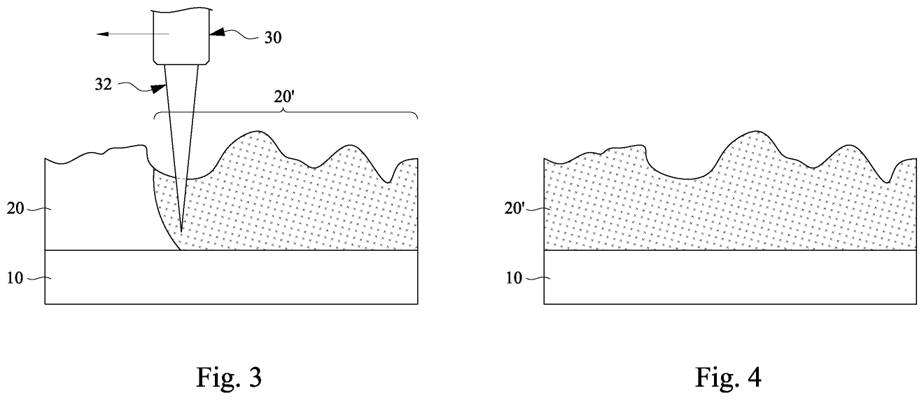

FIGS. 2 and 3 illustrate the performing of a laser treatment process on the upper layer 20, in accordance with some embodiments. During the laser treatment process, a laser source 30 directs a laser beam 32 into the upper layer 20 to modify a portion of the upper layer 20. For example, the laser source 30 may generate a laser beam 32 and focus the laser beam 32 into the material of the upper layer 20. During the laser treatment process, energy from the laser beam 32 is absorbed by a region of the upper layer 20 near the laser beam 32, modifying the material of the upper layer 20 in that region. For example, energy from the laser beam 32 may heat the material of the upper layer 20 near the laser beam 32, causing the material near the laser beam 32 to expand or undergo other chemical or structural changes. In some cases, the laser beam 32 causes material to expand, which increases internal stress and can cause cracking, fracturing, or deformation of the material. Accordingly, after performing the laser treatment process, the modified material is structurally weaker than unmodified material. In this manner, a region of the upper layer 20 is modified by the energy of the laser beam 32, forming a modified region 20′ of the upper layer 20.

During the laser treatment process, the laser beam 32 may be translated across the upper layer 20, extending the modified region 20′. For example, FIG. 2 illustrates the laser source 30 at a first location over the upper layer 20, and FIG. 3 illustrates the laser source 30 after having been translated to a second location over the upper layer 20. As the laser beam 32 is translated across the upper layer 20, the energy from the laser beam 32 continually modifies the material of the upper layer 20, extending the modified region 20′ across the upper layer 20. In some embodiments, the laser treatment process may be performed over the entire upper layer 20, modifying the entire upper layer 20. In this manner, the modified region 20′ may cover the entire upper layer 20, and in such cases the upper layer 20 may be referred to as a modified upper layer 20′ (e.g., see FIG. 4). Accordingly, a modified upper layer 20′ may be formed after completion of a laser treatment process, in some cases. A modified upper layer 20′ may be formed, for example, by translating the laser beam 32 along a path that covers some or all of the area of the upper layer 20 in a suitable pattern, such as path having a raster pattern, a spiral pattern, a grid pattern, or any other suitable pattern. The laser beam 32 may be moved continuously (e.g., scanned) across a portion of the upper layer 20, or the laser beam 32 may be moved across a portion of the upper layer 20 in one or more discrete steps. In some cases, laser source 30 may remain stationary when the laser beam 32 is turned on or when the laser beam 32 is applied to the upper layer 20. In some cases, the laser beam 32 may be periodically or occasionally turned off during the laser treatment process. Other configurations, applications, movements, or operations of the laser source 30 during the laser treatment process are possible. In some embodiments, the upper layer 20 may be modified using more than one “pass” of the laser beam 32, such as by performing multiple laser treatments along interlaced paths, or the like. In some embodiments, multiple laser treatment processes may be performed on the same region(s) of the upper layer 20. For example, a laser treatment process may be performed on a previously-formed modified region 20′ or modified upper layer 20′. In some embodiments, multiple modified regions 20′ may be formed, or only a portion of the upper layer 20 may be modified using the laser treatment process.

In some embodiments, the laser treatment process modifies the upper layer 20 into a modified upper layer 20′ to enable easier and/or more uniform removal of the upper layer 20 using a planarization process. A planarization process may include a chemical mechanical polish (CMP) process, a grinding process, or another suitable planarization process. In some cases, the laser treatment process may structurally weaken the upper layer 20 through laser-induced heating, laser-induced damage, or laser-induced chemical change. For example, heating the material of the upper layer 20 using the laser beam 32 may cause the material of the upper layer 20 to expand, modifying the material of the upper layer 20 to have more structural defects, broken bonds, etc. In some cases, the modified upper layer 20′ may have a larger volume than the unmodified upper layer 20. This is an example, and a laser treatment process may form a modified upper layer 20′ by modifying the characteristics of an upper layer 20 in other ways. Forming a modified upper layer 20′ that is structurally weaker than the unmodified upper layer 20 can allow for easier removal of the modified upper layer 20′ using a planarization process. For example, a modified upper layer 20′ may have a greater removal rate during a planarization process than an unmodified upper layer 20, or than an underlying unmodified layer (e.g. the lower layer 10). In some cases, a modified upper layer 20′ may be more chemically reactive or have a greater etch rate during a planarization process than an unmodified upper layer 20. In this manner, performing a laser treatment process on a layer as described herein can thus reduce the time, materials, or cost of planarizing the layer.

The laser source 30 may include a laser diode or any suitable source of laser emission configured to generate a laser beam 32, with appropriate optics, lenses, optical fibers, etc. In some embodiments, the laser beam 32 has a wavelength in the range of about 300 nm to about 1500 nm, though other wavelengths are possible. The laser source 30 may generate a laser beam 32 with a pulse dwell time in the range of about 1 femtosecond (fs) to about 1000 nanoseconds (ns), and may generate a laser beam 32 with a pulse energy in the range of about 1 microjoules (μJ) to about 1000 millijoules (mJ), though other laser characteristics are possible. The particular wavelength(s) or laser power used in the laser treatment process may depend on properties of the upper layer 20 and/or the lower layer 10. In some embodiments, the laser beam 32 may be continuously applied to the upper layer 20 during at least a portion of the laser treatment process. In other embodiments, the laser beam 32 may be pulsed during at least a portion of the laser treatment process. In some embodiments, the power or other properties of the laser beam 32 may be controlled or adjusted to control the amount or depth of the modification. For example, the properties of the laser beam 32 may be adjusted according to portions of the lower layer 10 and/or upper layer 20 having different compositions.

In some embodiments, the laser beam 32 may be a focused beam, with the focal point 33 of the laser beam 32 located within the upper layer 20. In other embodiments, the laser beam 32 may be focused at or near a top surface of the upper layer 20, or at or near a bottom surface of the upper layer 20. In some embodiments, the focal point 33 of the laser beam 32 is above a bottom surface of the upper layer 20. For example, the focal point 33 of the laser beam 32 may be a distance D1 above the lower layer 10 (e.g., a distance D1 above a bottom surface of the upper layer 20). The distance D1 may be in the range of about 1 μm to about 100 μm, though other distances are possible. In some cases, the target removal surface within the structure may be represented by the dashed line indicating the distance D1. The distance D1 may depend on the properties of the upper layer 20 and/or the lower layer 10. For example, the energy (e.g., heating) from the laser beam 32 may spread outward from the laser beam 32, such that a bottom portion of the upper layer 20 is modified by the laser beam 32 even though the laser beam 32 is not focused on the bottom portion of the upper layer 20. The focal point 33 of the laser beam 32 may be separated from the lower layer 10 (e.g., by a distance D1) to reduce or minimize modification of the lower layer 10 by the laser beam 32. In some cases, a region of the upper layer 20 at or near the focal point 33 of the laser beam 32 may undergo a greater amount of modification than regions farther from the focal point 33, or may undergo modification at a greater rate than regions farther from the focal point 33. For example, heating of the upper layer 20 may be greatest at the focal point 33, in some cases. In this manner, in some cases, regions of the upper layer 20 near a top surface of the upper layer 20 may be less modified than regions of the upper layer 20 near a bottom surface of the upper layer 20. In some cases, controlling the focal point 33 to be located at or near a constant distance (e.g., distance D1) above the lower layer 10 can improve planarity of the resulting top surface of the lower layer 10 after planarization. In some embodiments, the depth of the focal point 33 may be controlled or adjusted to control the depth of the modified upper layer 20′.

Turning to FIG. 4, the upper layer 20 is shown after completion of the laser treatment process, in accordance with some embodiments. In the example of FIG. 4, the entire upper layer 20 has been modified by the laser treatment process, forming a modified upper layer 20′. In other embodiments, only a portion of the upper layer 20 is modified by the laser treatment process, thus forming one or more modified regions 20′ in the upper layer 20 rather than forming a fully modified upper layer 20′. In some cases, an upper portion of the lower layer 10 may also be modified by the laser treatment process.

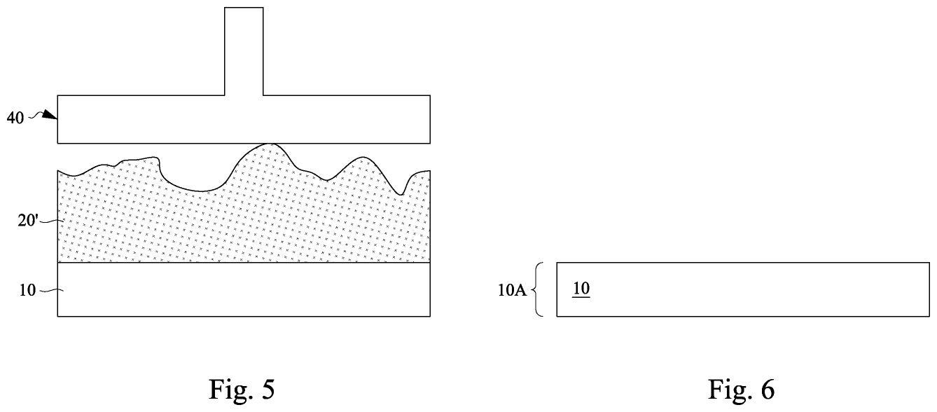

In FIGS. 5-6, a planarization process is performed to remove the modified upper layer 20′, in accordance with some embodiments. FIG. 5 schematically illustrates the modified upper layer 20′ during the planarization process, and FIG. 6 illustrates the lower layer 10 after removal of the modified upper layer 20′ by the planarization process. FIG. 5 illustrates a planarization tool 40 as it removes portions of the modified upper layer 20′. The planarization tool 40 in FIG. 5 represents any suitable CMP tool, grinding tool, or the like. For example, the planarization process may be a CMP process or the like, in which the planarization tool 40 may comprise a polishing pad or the like. A slurry may be used during the planarization process, in some cases. As described previously, a modified upper layer 20′ may be easier to remove using the planarization tool 40 than an unmodified upper layer 20. Thus, in some cases, the conditions, materials (e.g., slurry, polishing pad, etc.), or parameters (e.g., pressure, rotation speed, etc.) used by the planarization tool 40 may be different for removing a modified upper layer 20′ than for removing an unmodified upper layer 20. In some cases, because the modified upper layer 20′ is easier to remove, the materials of the polishing tool 40 may need to be replaced less frequently.

In some cases, the use of a laser treatment process as described herein can allow for improved planarity after performing a planarization process. For example, the top surface of the lower layer 10 after the planarization process may be more flat if the upper layer 20 is modified into a modified upper layer 20 by the laser treatment process than if the upper layer 20 is unmodified. The improved planarity of the lower layer 10 may be due to the easier removal of the modified upper layer 20′ relative to the unmodified lower layer 10, in some cases. Additionally, controlling the focal point 33 of the laser beam 32 to be an approximately contact distance (e.g., distance D1) above the lower layer 10 can result in a more uniform planarization. In this manner, the techniques described herein can reduce the sensitivity of planarization to surface topography, and can reduce uneven topography, dishing, roughness, bumps, or other deviations from planarity in a planarized layer.

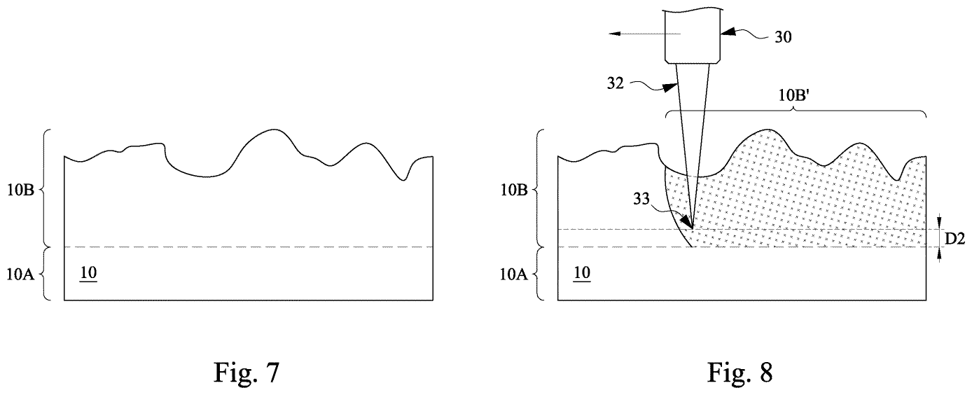

FIGS. 7 through 10 illustrate intermediate steps in a planarization process including a laser treatment process, in accordance with some embodiments. The planarization process described for FIGS. 7-10 is similar to that described previously for FIGS. 1-6, except that instead of removing a separate upper layer and leaving a remaining lower layer, the planarization process removes an upper portion of a layer and leaves a remaining lower portion of the same layer. For example, FIG. 7 illustrates a cross-sectional view of a layer 10, in accordance with some embodiments. The subsequently performed planarization process removes an upper region 10B of the layer 10, leaving a lower region 10A of the layer 10 remaining. After the planarization process, the lower region 10A of the layer 10 has a planarized top surface. The techniques described herein can improve the planarity and uniformity of the lower region 10A. In other embodiments, the planarization process can remove an upper portion of first layer and a portion of the first layer covering a second layer. In such embodiments, the planarization process may expose a top surface of the first layer and a top surface of the second layer.

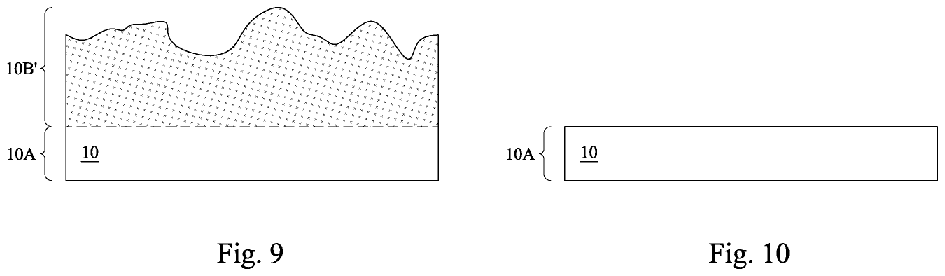

FIGS. 8 and 9 illustrate the performing of a laser treatment process on the layer 10, in accordance with some embodiments. During the laser treatment process, a laser source 30 directs a laser beam 32 into the layer 10 to modify an upper region 10B of the layer 10. For example, the laser source 30 may generate a laser beam 32 and focus the laser beam 32 into the material of the layer 10. In this manner, a portion of the upper region 10B is modified by the laser beam 32 into a modified upper region 10B′, as shown in FIG. 8. In some embodiments, the focal point 33 of the laser beam 32 is above a bottom surface of the lower region 10A. For example, the focal point 33 of the laser beam 32 may be a distance D2 above the lower region 10A (e.g., a distance D2 above the bottom of the upper region 10B). The distance D2 may be in the range of about 1 μm to about 100 μm, though other distances are possible. In some embodiments, the depth of the focal point 33 into the layer 10 may be controlled or adjusted to control the depth of the modified upper region 10B′. In some embodiments, the power or other properties of the laser beam 32 may be controlled or adjusted to control the amount or depth of the modification. For example, the properties of the laser beam 32 may be adjusted according to portions of the layer 10 having different compositions. Offsetting the focal point 33 from the lower region 10A may reduce modification of the lower region 10A. During the laser treatment process, the laser beam 32 may be translated across the layer 10, extending the modified upper region 10B′.

In FIG. 9, the layer 10 is shown after completion of the laser treatment process, in accordance with some embodiments. In the example of FIG. 9, the entire upper region 10B has been modified by the laser treatment process, forming a modified upper region 10B′. In other embodiments, only a portion of the upper region 10B is modified by the laser treatment process, thus forming one or more modified upper regions 10B′ in the layer 10. In some cases, an upper portion of the lower region 10A may also be modified by the laser treatment process.

In FIG. 10, a planarization process is performed to remove the modified upper region 10B′, in accordance with some embodiments. The planarization process may be a CMP process or the like, and may be similar to the planarization process described previously for FIG. 5. As described previously, a modified upper region 10B′ may be easier to remove using a planarization process than an unmodified upper region 10B. The modified upper region 10B′ may also be easier to remove than the lower (unmodified) region 10A. In some cases, the use of a laser treatment process as described herein can allow for improved planarity after performing a planarization process to remove an upper region of a layer. For example, the top surface of the lower region 10A after the planarization process may be more flat if the upper region 10B is modified into a modified upper region 10B′ by the laser treatment process than if the upper region 10B is unmodified. The improved planarity of the lower layer 10 may be due to the easier removal of the modified upper layer 20′ relative to the unmodified lower layer 10, in some cases. In this manner, the techniques described herein can result in flatter and more uniform planarized surfaces.

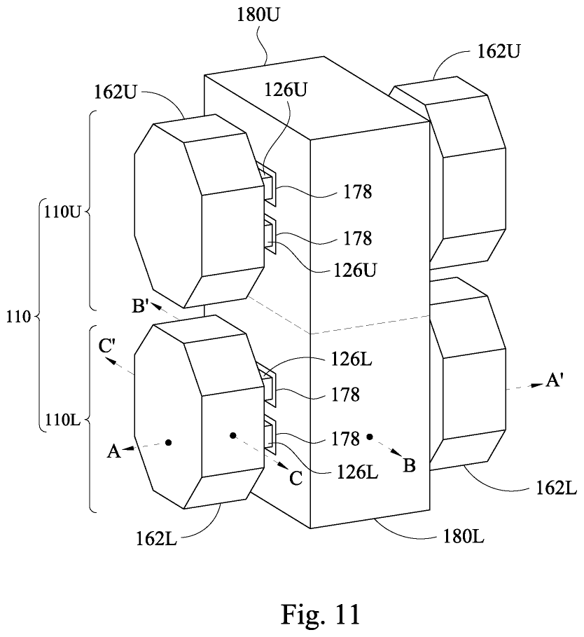

As an example of using the laser treatment process in a planarization process, FIGS. 11 through 27 illustrate intermediate stages in the formation of a stacking transistor structure, in accordance with some embodiments. The stacking transistor structure may be a Complementary Field-Effect Transistor (CFET) structure, in some cases. The embodiment of FIGS. 11-27 is intended as an illustrative example, and the techniques described herein may be utilized as part of any suitable process and may be used to form any suitable devices or structures. For example, the techniques described herein may be utilized to form Fin Field-Effect Transistor (FinFET) structures, planar FET structures, nanostructure-FET structures, other CFET structures, packages, chips, dies, or other types of devices or other types of structures. Any planarization process may also include a laser treatment process, when appropriate or desired.

FIG. 11 illustrates an example of a stacking transistor 110 (including FETs (transistors) 110U and 110L) in accordance with some embodiments. FIG. 11 is a three-dimensional view, and some features of the stacking transistor are omitted for illustration clarity. The stacking transistor 110 includes multiple vertically stacked FETs. For example, a stacking transistor may include a lower nanostructure-FET 110L of a first device type (e.g., n-type/p-type) and an upper nanostructure-FET 110U of a second device type (e.g., p-type/n-type). When the stacking transistor is a CFET, the second device type of the upper nanostructure-FET 110U is opposite to the first device type of the lower nanostructure-FET 110L. The nanostructure-FETs 110U and 110L include semiconductor nanostructures 126 (including lower semiconductor nanostructures 126L and upper semiconductor nanostructures 126U), where the semiconductor nanostructures 126 act as the channel regions for the nanostructure-FETs. The lower semiconductor nanostructures 126L are for the lower nanostructure-FET 110L, and the upper semiconductor nanostructures 126U are for the upper nanostructure-FET 110U. In other embodiments, the stacking transistors may be applied to other types of transistors (e.g., FinFETs, or the like) as well.

Gate dielectrics 178 encircle the respective semiconductor nanostructures 126. Gate electrodes 180 (including a lower gate electrode 180L and an upper gate electrode 180U) are over the gate dielectrics 178. Source/drain regions 162 (including lower source/drain regions 162L and upper source/drain regions 162U) are disposed on opposing sides of the gate dielectrics 178 and the respective gate electrodes 180. Each of the source/drain regions 162 may refer to a source or a drain, individually or collectively dependent upon the context. Isolation features (not shown) may be formed to separate desired ones of the source/drain regions 162 and/or desired ones of the gate electrodes 180.

FIG. 11 further illustrates reference cross-sections that are used in later figures. Cross-section A-A′ is a vertical cross-section that is parallel to a longitudinal axis of the semiconductor nanostructures 126 of a stacking transistor and in a direction of, for example, a current flow between the source/drain regions 162 of the stacking transistor. Cross-section B-B′ is a vertical cross-section that is perpendicular to cross-section A-A′ and along a longitudinal axis of a gate electrode 180 of the CFET. Cross-section C-C′ is a vertical cross-section that is parallel to cross-section B-B′ and extends through the source/drain regions 162 of the stacking transistor. Subsequent figures may refer to these reference cross-sections for clarity.

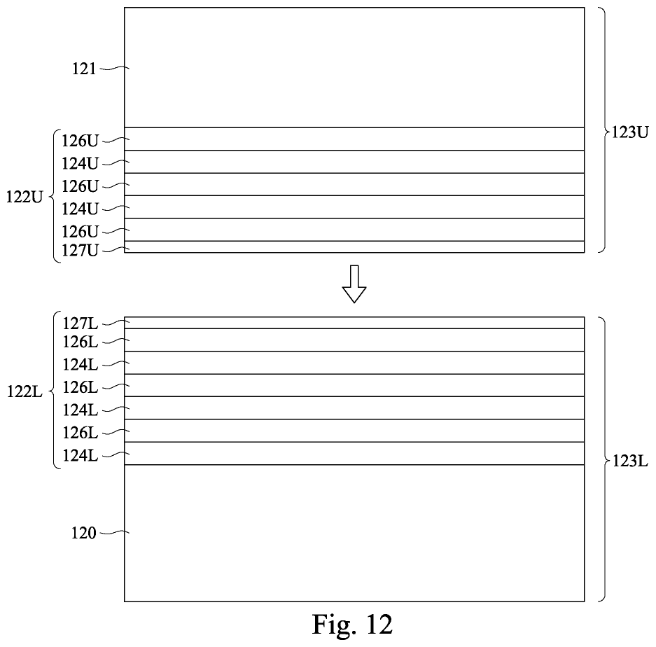

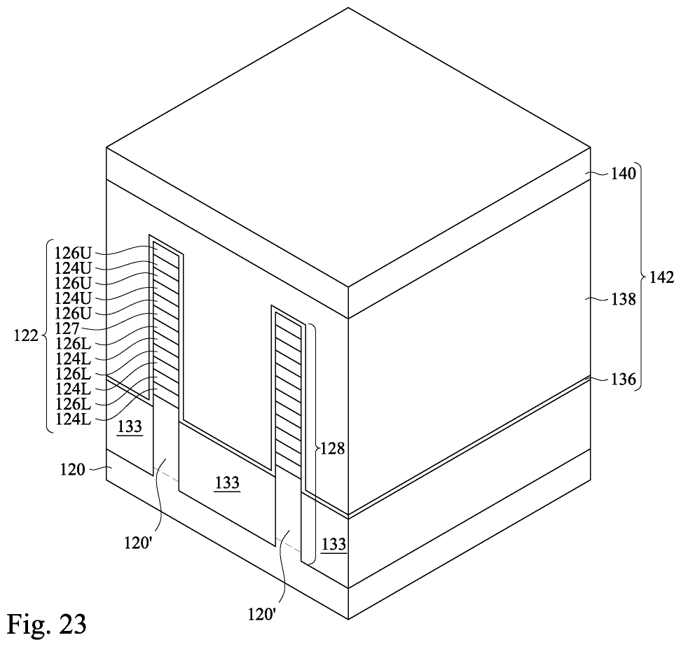

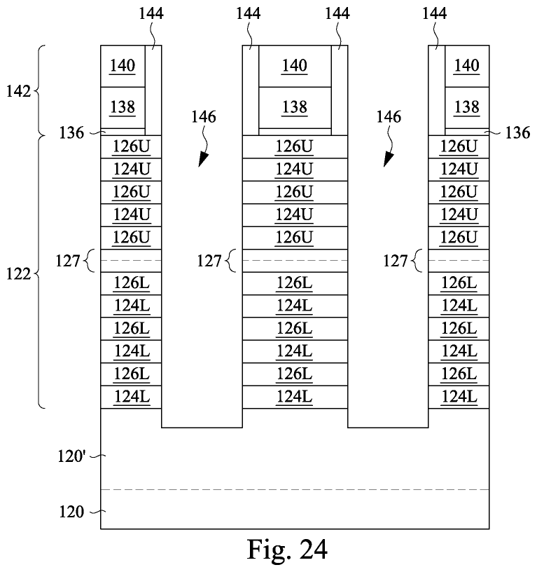

FIGS. 12 through 27 illustrate views of intermediate stages in the formation of stacking transistors (as schematically represented in FIG. 11) in accordance with some embodiments. FIGS. 12-22 illustrate cross-sectional views, FIG. 23 illustrates a three-dimensional view, and FIGS. 24-27 illustrate cross-sectional views. In the subsequent discussion, unless specified otherwise, the cross-sectional views are vertical cross-sectional views along a similar cross-section as vertical reference cross-section A-A′ in FIG. 11.

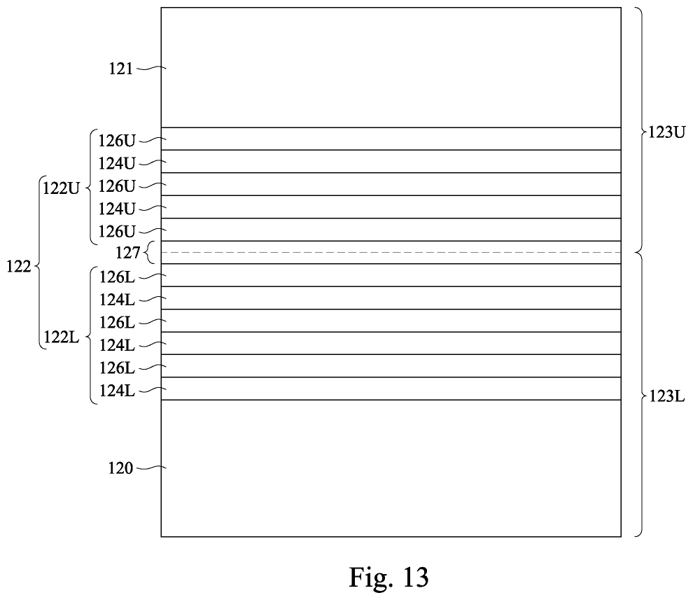

In FIGS. 12-13, a lower wafer 123L is bonded to an upper wafer 123U, in accordance with some embodiments. FIG. 12 illustrates the wafers 123L/123U prior to bonding, and FIG. 13 illustrates the wafers 123L/123U after bonding. The lower wafer 123L includes a multi-layer stack 122L on a substrate 120, and the upper wafer 123U includes a multi-layer stack 122U on a substrate 121. The substrates 120/121 may be semiconductor substrates, such as a bulk semiconductor, which may be doped (e.g., with a p-type or an n-type dopant) or undoped. Other substrates, such as a multi-layered or gradient substrate may also be used. In some embodiments, the semiconductor material of the substrates 120/121 may include silicon, germanium, carbon-doped silicon, a III-V compound semiconductor; or the like, or combinations thereof.

The multi-layer stack 122L of the lower wafer 123L includes dummy layers 124L, semiconductor layers 126L, and a bonding layer 127L, and the multi-layer stack 122U of the upper wafer 123U includes dummy layers 124U, semiconductor layers 126U, and a bonding layer 127U. The multi-layer stacks 122L/122U may be formed of another number of layers than shown. In some embodiments, the dummy layers 124L/124U are formed of a first semiconductor material, the semiconductor layers 126L/126U are formed of a second semiconductor material, and the bonding layers 127L/127U are formed of a dielectric material. The first and second semiconductor materials may be selected from the candidate semiconductor materials of the substrates 120/121. The semiconductor layers 126L and the semiconductor layers 126U may be formed of the same second semiconductor material, or may be formed of different semiconductor materials. The first and second semiconductor materials have a high etching selectivity to one another. As such, the dummy layers 124L/124U may be selectively removed in subsequent process steps without significantly removing the semiconductor layers 126L/126U.

In some embodiments, the dummy layers 124L/124U are formed of or comprise silicon germanium and the semiconductor layers 126L/126U are formed of silicon. To form the multi-layer stacks 122L and 122U, layers of the first and second semiconductor materials (arranged as illustrated and described above) may be deposited over the respective substrates 120 and 121. The layers of the first and second semiconductor materials may be grown using a process such as Vapor Phase Epitaxy (VPE) or Molecular Beam Epitaxy (MBE), deposited using a process such as Chemical Vapor Deposition (CVD) process or an Atomic Layer deposition (ALD) process, or the like.

In some embodiments, the bonding layers 127L/127U are formed of or comprise a dielectric material suitable for direct bonding (e.g., fusion bonding, dielectric-to-dielectric bonding, oxide-to-oxide bonding, or the like). For example, the bonding layers 127L/127U may comprise silicon oxide, silicon oxynitride, or the like. The bonding layer 127L and the bonding layer 127U may be similar materials or different materials. In some embodiments, the bonding layers 127L/127U may be a material that has a high etching selectivity to the first semiconductor material and/or the second semiconductor material, and thus may be removed at a faster rate than the first semiconductor material and/or the second semiconductor material in subsequent processes. In other embodiments, the bonding layers 127L/127U are formed of a semiconductor material.

In FIG. 13, the structure is shown after bonding the bonding layer 127U of the upper wafer 123U to the bonding layer 127L of the lower wafer 123L. The bonding layer 127U may be bonded to the bonding layer 127L using a suitable direct bonding process. For example, surfaces of the bonding layers 127L/127U may be treated using a surface preparation process, and then the bonding layer 127U may be pressed against the bonding layer 127L. A thermal treatment, such as an anneal, may be performed in some cases. Other bonding processes are possible. The bonding layers 127L and 127U collectively form an isolation layer 127 that separates the upper multi-layer stack 122U from the lower multi-layer stack 122L. The upper multi-layer stack 122U and the lower multi-layer stack 122L collectively form a single multi-layer stack 122 between the substrate 120 and the substrate 121.

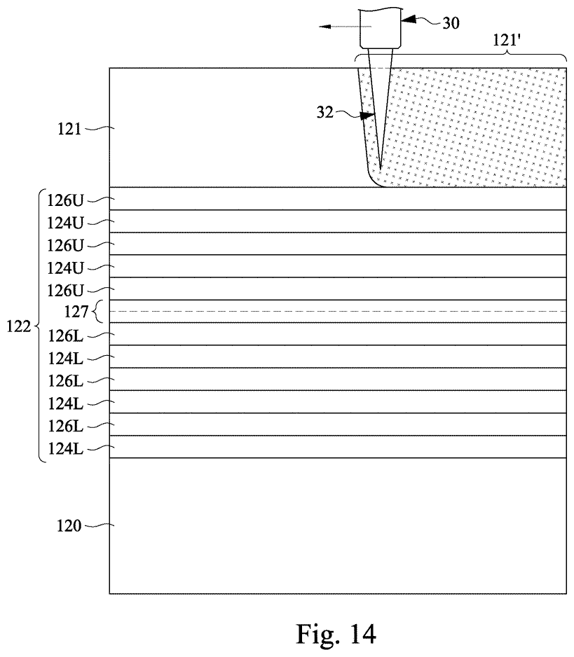

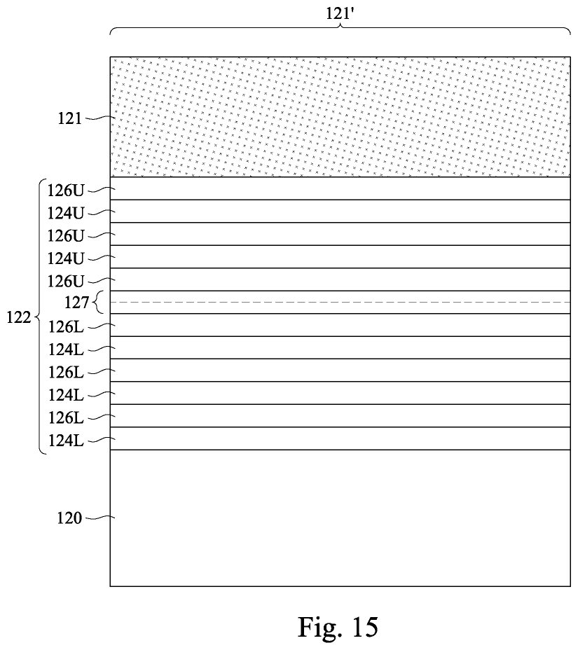

In FIG. 14, a laser treatment process is performed on the substrate 121 to modify the material of the substrate 121. The laser treatment process may be similar to that described previously for FIGS. 2-3. For example, a laser source 30 may generate a laser beam 32 that penetrates the substrate 121, modifying the material of the substrate 121 and forming a modified region 121′ of the substrate 121. The laser source 30 may be scanned across the substrate 121 to extend the modified region 121′. In some cases, the layer of the multi-layer stack 122 underneath the substrate 121 (e.g., the semiconductor layer 126U) may have little or no modification. FIG. 15 illustrates the structure after the laser treatment process has been performed, and the entire substrate 121 is modified. In other words, the modified region 121′ of the substrate 121 extends across the substrate 121.

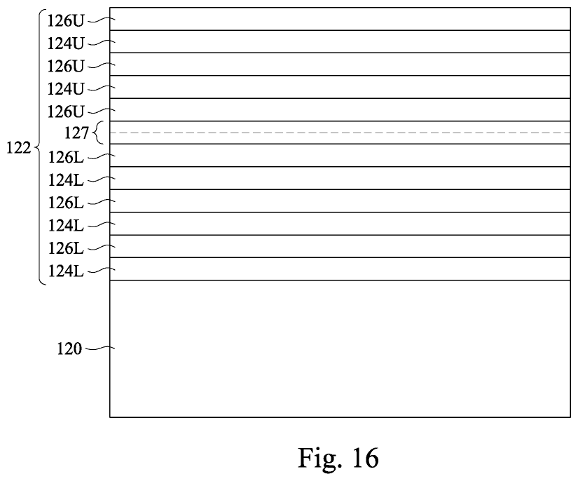

In FIG. 16, a planarization process is performed to remove the substrate 121, in accordance with some embodiments. The planarization process may include, for example, a CMP process, a grinding process, or the like. Removing the substrate 121 exposes a surface of a layer of the multi-layer stack 122. For example, in the embodiment of FIG. 16, removing the substrate 121 exposes a surface of the top-most semiconductor layer 126U. In some cases, performing the laser treatment process on the substrate 121 prior to its removal can result in a more planar and more uniform planarized surface (e.g. the surface of the top-most semiconductor layer 126U).

While FIGS. 12-16 illustrate the formation of a multi-layer stack 122 on a substrate 120 using bonding and planarization techniques, the multi-layer stack 122 may be formed using other techniques. For example, in other embodiments, all of the various layers of the multi-layer stack 122 may be grown or deposited on the substrate 120. In such embodiments, the various layers of the multi-layer stack 122 may be formed using techniques similar to those used to form the multi-layer stacks 122L/122U. The following process steps may be performed on a similar structure that was formed using any suitable technique.

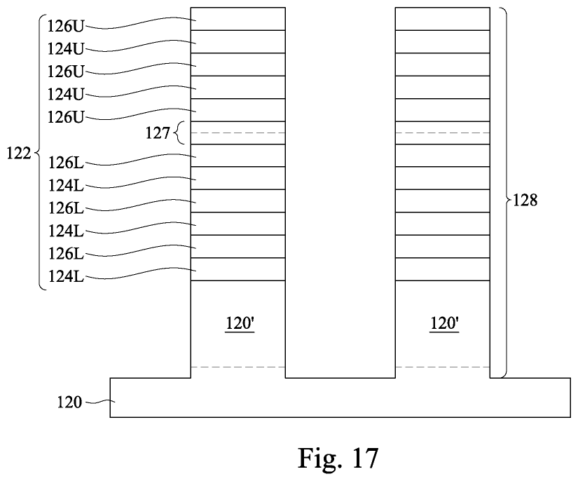

In FIG. 17, the multi-layer stack 122 and the substrate 120 are patterned to form semiconductor strips 128, in accordance with some embodiments. The semiconductor strips 128 are formed extending upwards from the substrate 120. Each of the semiconductor strips 128 includes semiconductor strips 120′ (patterned portions of the substrate 120, also referred to as fins 120′) and a portion of the multi-layer stack 122 (also referred to as a multi-layer stack 122). The various layers of the multi-layer stack 122 are referred to as nanostructures hereinafter. Specifically, the multi-layer stack 122 includes dummy nanostructures 124L, dummy nanostructures 124U, lower semiconductor nanostructures 126L, and upper semiconductor nanostructures 126U. Dummy nanostructures 124L and dummy nanostructures 124U may subsequently be collectively referred to as dummy nanostructures 124. The lower semiconductor nanostructures 126L and the upper semiconductor nanostructures 126U may subsequently be collectively referred to as semiconductor nanostructures 126.

The lower semiconductor nanostructures 126L provide channel regions for lower nanostructure-FETs of the subsequently formed CFETs. The upper semiconductor nanostructures 126U provide channel regions for upper nanostructure-FETs of the subsequently formed CFETs. The semiconductor nanostructures 126 that are immediately above or below (e.g., in contact with) the isolation layers 127 may be used for isolation and may or may not act as channel regions for the CFETs. The isolation layer 127s are subsequently replaced with isolation structures that define boundaries of the lower nanostructure-FETs and the upper nanostructure-FETs.

The patterning process may be applied to the layers of the first and second semiconductor materials, the dielectric material, and the substrate 120 to define the semiconductor strips 128, which include the fins 120′, the dummy nanostructures 124, the isolation layers 127, and the semiconductor nanostructures 126. The fins 120′, the isolation layers 127, and the nanostructures 124/126 may be patterned by any suitable techniques. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the various underlying layers and the substrate 120. The etching may be performed by any acceptable etch process, such as a Reactive Ion Etch (RIE), Neutral Beam Etch (NBE), the like, or a combination thereof. The etching may be anisotropic.

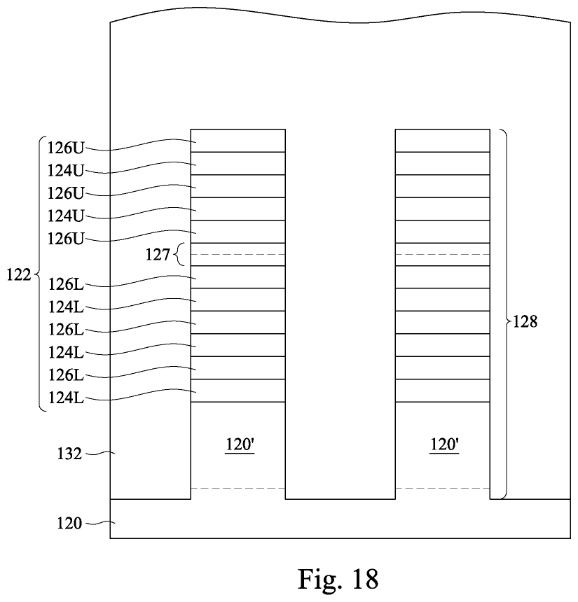

In FIG. 18, dielectric material 132 is deposited over the semiconductor strips 128, in accordance with some embodiments. Shallow Trench Isolation (STI) regions 133 are subsequently formed from the dielectric material 132. As shown in FIG. 18, the dielectric material 132 is formed over the substrate 120 and between adjacent semiconductor strips 128. In some embodiments, the dielectric material 132 includes a dielectric liner and a dielectric fill material over the dielectric liner. Each of the dielectric liner and the dielectric fill material may include an oxide such as silicon oxide, a nitride such as silicon nitride, the like, or a combination thereof. The dielectric material 132 may be deposited using suitable deposition processes such as ALD, High-Density Plasma CVD (HDP-CVD), Flowable CVD (FCVD), the like, or a combination thereof. In some embodiments, the dielectric material 132 includes silicon oxide formed by a FCVD process followed by an anneal process.

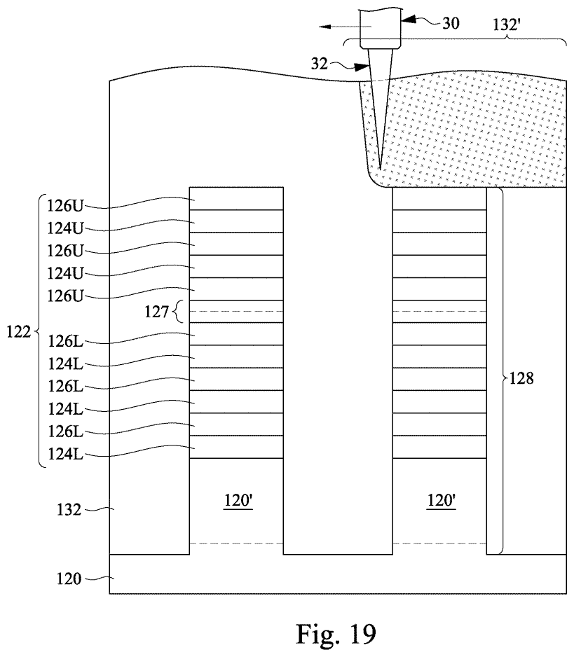

In FIG. 19, a laser treatment process is performed on the dielectric material 132 to modify an upper region of the dielectric material 132. The laser treatment process may be similar to that described previously for FIGS. 2-3. For example, a laser source 30 may generate a laser beam 32 that penetrates the dielectric material 132, modifying an upper region of the dielectric material 132 and forming a modified region 132′ of the dielectric material 132. The modified upper region of the dielectric material 132 may extend over the semiconductor strips 128. In some cases, the entire upper region of the dielectric material 132 may be modified. In some embodiments, modifying the entire upper region of the dielectric material 132 can allow for improved planarity and reduce loading effects, for example, due to different densities or different pitches of semiconductor strips 128 in different regions of the substrate 120. In other embodiments, a modified upper region may include only a portion of the upper region of the dielectric material 132 that covers or is near a set of semiconductor strips 128. In some embodiments, the locations, areas, depths, or amounts of modification of the dielectric material 132 in different regions may be chosen to compensate for loading effects, thus allowing for improved planarity and uniformity. The laser source 30 may be scanned across the dielectric material 132 to extend the modified region 132′. As shown in FIG. 19, the laser treatment process may modify the portion of the dielectric material 132 over the semiconductor strips 128. Accordingly, the bottom of the modified region 132′ may be approximately level with top surfaces of the semiconductor strips 128. In other embodiments, the bottom of the modified region 132′ may be above or below top surfaces of the semiconductor strips 128. In some cases, upper portions of the top-most layers of the semiconductor strips 128 may be modified by the laser treatment process.

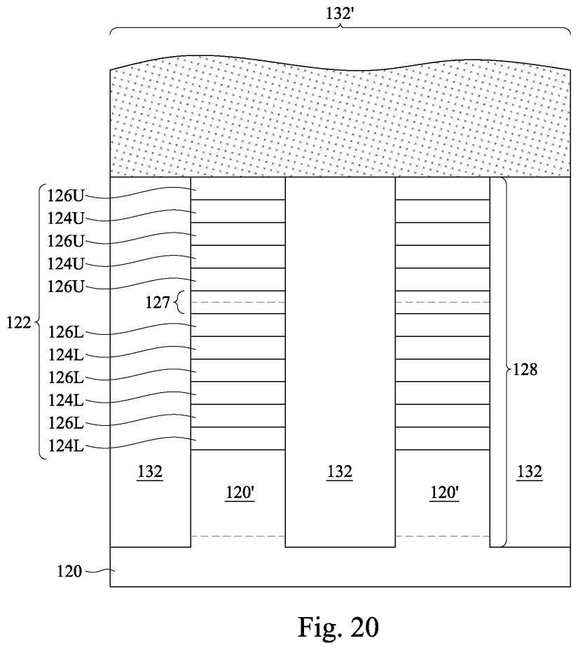

FIG. 20 illustrates the structure after the laser treatment process has been performed, and entire upper portion of the dielectric material 132 above the semiconductor strips 128 has been modified. In other words, the modified region 132′ of the dielectric material 132 extends over the semiconductor strips 128 and extends over the dielectric material 132 between the semiconductor strips 128.

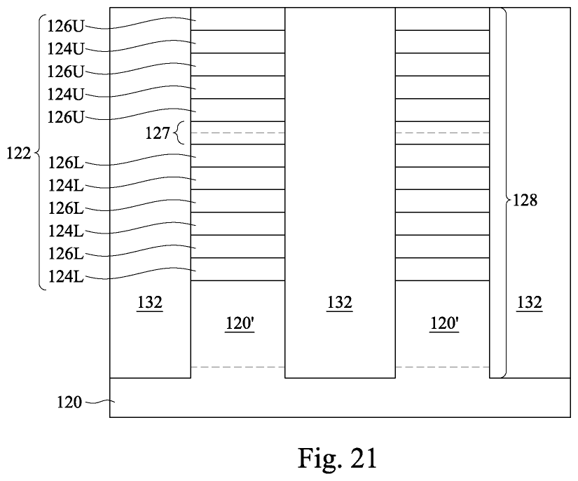

In FIG. 21, a planarization process is performed to remove the modified region 132′ of the dielectric material 132, in accordance with some embodiments. The planarization process may include, for example, a CMP process, a grinding process, or the like. Removing the modified region 132′ exposes the semiconductor strips 128. For example, in the embodiment of FIG. 20, removing the modified region 132′ exposes a surface of the top-most semiconductor layer 126U. After performing the planarization process, top surfaces of the dielectric material 132 and the semiconductor strips 128 may be level. In some cases, performing the laser treatment process on the dielectric material 132 prior to planarization can result in a more planar and more uniform planarized surface.

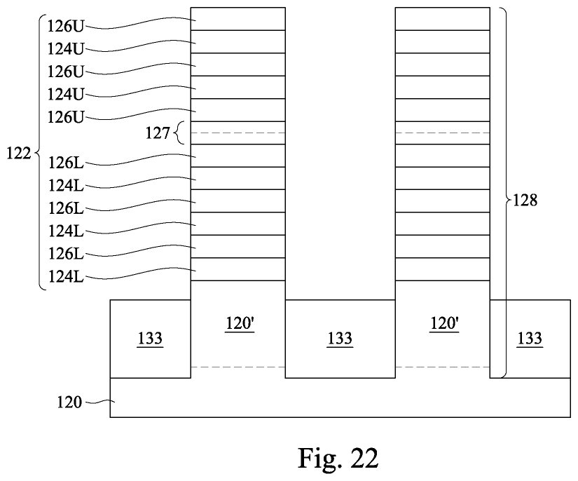

In FIG. 22, the dielectric material 132 is recessed, with remaining portions of the dielectric material 132 forming the STI regions 133. The dielectric material 132 may be recessed using an etching process, which may include a wet etching process and/or a dry etching process. The dielectric material 132 may be recessed such that upper portions of semiconductor strips 128 (including the multi-layer stacks 122) protrude higher than the remaining STI regions 133. Top surfaces of the STI regions 133 may be higher than, lower than, or about the same height as top surfaces of the fins 120′.

In FIG. 23, dummy gate stacks 142 are formed over the semiconductor strips 128, in accordance with some embodiments. The dummy gate stacks 142 may be formed over and along sidewalls of the upper portions of the semiconductor strips 128 (e.g., the portions that protrude higher than the STI regions 133). Forming the dummy gate stacks 142 may include forming a dummy dielectric layer 136 on the semiconductor strips 128. The dummy dielectric layer 136 may be formed of or comprise, for example, silicon oxide, silicon nitride, a combination thereof, or the like, and may be deposited or thermally grown according to acceptable techniques. A dummy gate layer 138 is formed over the dummy dielectric layer 136. The dummy gate layer 138 may be deposited, for example, through Physical Vapor Deposition (PVD), CVD, or other techniques, and then planarized using a suitable planarization process. The planarization process may include a laser treatment process, in some embodiments. The material of dummy gate layer 138 be conductive or non-conductive, and may be selected from a group including amorphous silicon, polycrystalline-silicon (polysilicon), poly-crystalline silicon-germanium (poly-SiGe), or the like. A mask layer 140 is formed over the planarized dummy gate layer 138, and may include, for example, silicon nitride, silicon oxynitride, or the like. Next, the mask layer 140 may be patterned using suitable photolithography and etching techniques to form a mask, which is then used to etch and pattern the dummy gate layer 138, and possibly used to pattern the dummy dielectric layer 136. The remaining portions of the mask layer 140, the dummy gate layer 138, and the dummy dielectric layer 136 form the dummy gate stacks 142.

In FIG. 24, gate spacers 144 and source/drain recesses 146 are formed, in accordance with some embodiments. First, the gate spacers 144 are formed over the multi-layer stacks 122 and on exposed sidewalls of dummy gate stacks 142. The gate spacers 144 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 146 are formed in semiconductor strips 128. The source/drain recesses 146 are formed through etching, and may extend through the multi-layer stacks 122 and into the fins 120′. The bottom surfaces of the source/drain recesses 146 may be at a level above, below, or level with the top surfaces of the STI regions 133. In the etching processes, the gate spacers 144 and the dummy gate stacks 142 mask some portions of the semiconductor strips 128. The etching may include a single etch process or multiple etch processes. Timed etch processes may be used to stop the etching of the source/drain recesses 146 upon source/drain recesses 146 reaching a desired depth.

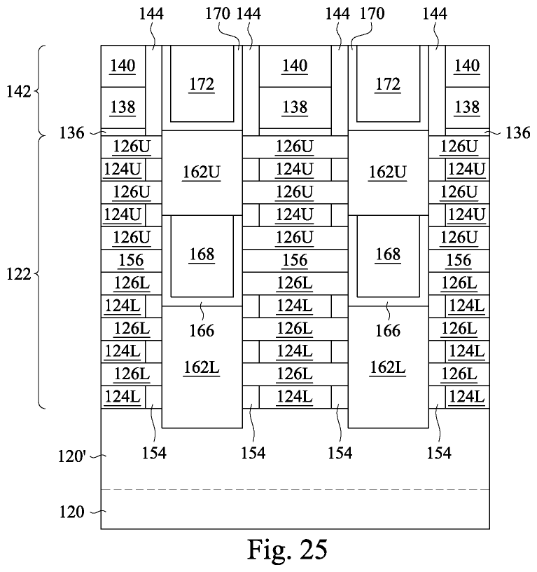

In FIG. 25, inner spacers 154 and dielectric isolation layers 156 are formed. Forming inner spacers 154 may include an etching process that laterally etches the dummy nanostructures 124, recessing sidewalls of the dummy nanostructures 124. The isolation layers 127 may also be removed using an etching process. The etching processes may be isotropic and may be selective to the etched materials. In this manner, the isolation layers 127 may be completely removed from between the lower semiconductor nanostructures 126L (collectively) and the upper semiconductor nanostructures 126U (collectively) without completely removing the dummy nanostructures 124. Because the dummy gate stacks 142 wrap around sidewalls of the semiconductor nanostructures 126 (see FIG. 23), the dummy gate stacks 142 may support the upper semiconductor nanostructures 126U so that the upper semiconductor nanostructures 126U do not collapse upon removal of the isolation layers 127. Further, although sidewalls of the dummy nanostructures 124 are illustrated as being straight after the etching, the sidewalls may be concave or convex.

Inner spacers 154 are formed on sidewalls of the recessed dummy nanostructures 124, and dielectric isolation layers 156 are formed between the upper semiconductor nanostructures 126U (collectively) and the lower semiconductor nanostructures 126L (collectively). As subsequently described in greater detail, source/drain regions will be subsequently formed in the source/drain recesses 146, and the dummy nanostructures 124 will be replaced with corresponding gate structures. The inner spacers 154 act as isolation features between the subsequently formed source/drain regions and the subsequently formed gate structures. Further, the inner spacers 154 may be used to prevent damage to the subsequently formed source/drain regions by subsequent etch processes, such as the etch processes used to form gate structures. Dielectric isolation layers 156, on the other hand, are used to isolate the upper semiconductor nanostructures 126U (collectively) from the lower semiconductor nanostructures 126L (collectively). Further, middle semiconductor nanostructures (ones of the semiconductor nanostructures 126 in contact with the dielectric isolation layers 156) and the dielectric isolation layers 156 may define the boundaries of the lower nanostructure-FETs and the upper nanostructure-FETs.

The inner spacers 154 and the dielectric isolation layers 156 may be formed by conformally depositing an insulating material in the source/drain recesses 146, on sidewalls of the dummy nanostructures 124, and between the upper and lower semiconductor nanostructures 126U and 126L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining on the sidewalls of the dummy nanostructures 124 (thus forming the inner spacers 154) and has portions remaining in between the upper and lower semiconductor nanostructures 126U and 126L (thus forming the dielectric isolation layers 156).

As also illustrated by FIG. 25, lower and upper epitaxial source/drain regions 162L and 162U are formed. The lower epitaxial source/drain regions 162L are formed in the lower portions of the source/drain recesses 146. The lower epitaxial source/drain regions 162L are in contact with the lower semiconductor nanostructures 126L and are not in contact with the upper semiconductor nanostructures 126U. Inner spacers 154 electrically insulate the lower epitaxial source/drain regions 162L from the dummy nanostructures 124L, which will be replaced with replacement gates in subsequent processes.

The lower epitaxial source/drain regions 162L are epitaxially grown, and have a conductivity type that is suitable for the device type (p-type or n-type) of the lower nanostructure-FETs. When lower epitaxial source/drain regions 162L are n-type source/drain regions, the respective material may include silicon or carbon-doped silicon, which is doped with an n-type dopant such as phosphorous, arsenic, or the like. When lower epitaxial source/drain regions 162L are p-type source/drain regions, the respective material may include silicon or silicon germanium, which is doped with a p-type dopant such as boron, indium, or the like. The lower epitaxial source/drain regions 162L may be in-situ doped, and may or may not be implanted with the corresponding p-type or n-type dopants. During the epitaxy of the lower epitaxial source/drain regions 162L, exposed surfaces of the upper semiconductor nanostructures 126U (e.g., sidewalls) may be masked to prevent undesired epitaxial growth on the upper semiconductor nanostructures 126U. After the lower epitaxial source/drain regions 162L are grown, the masks on the upper semiconductor nanostructures 126U may then be removed.

As a result of the epitaxy processes used for forming the lower epitaxial source/drain regions 162L, upper surfaces of the lower epitaxial source/drain regions 162L have facets which expand laterally outward beyond sidewalls of the multi-layer stacks 122. In some embodiments, adjacent lower epitaxial source/drain regions 162L remain separated after the epitaxy process is completed. In other embodiments, these facets cause neighboring lower epitaxial source/drain regions 162L of a same FET to merge.

A first contact etch stop layer (CESL) 166 and a first ILD 168 are formed over the lower epitaxial source/drain regions 162L. The first CESL 166 may be formed of a dielectric material having a high etching selectivity from the etching of the first ILD 168, such as silicon nitride, silicon oxide, silicon oxynitride, or the like, which may be formed by any suitable deposition process, such as CVD, ALD, or the like. The first ILD 168 may be formed of a dielectric material, which may be deposited by any suitable method, such as CVD, plasma-enhanced CVD (PECVD), or FCVD. The applicable dielectric material of the first ILD 168 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 168, followed by a planarization process and then an etch-back process. In some embodiments, the first ILD 168 is etched first, leaving the first CESL 166 unetched. An anisotropic etching process is then performed to remove the portions of the first CESL 166 higher than the recessed first ILD 168. After the recessing, the sidewalls of the upper semiconductor nanostructures 126U are exposed.

Upper epitaxial source/drain regions 162U are then formed in the upper portions of the source/drain recesses 146. The upper epitaxial source/drain regions 162U may be epitaxially grown from exposed surfaces of the upper semiconductor nanostructures 126U. The materials of upper epitaxial source/drain regions 162U may be selected from the same candidate group of materials for forming lower source/drain regions 162L, depending on the desired conductivity type of upper epitaxial source/drain regions 162U. The conductivity type of the upper epitaxial source/drain regions 162U may be opposite the conductivity type of the lower epitaxial source/drain regions 162L in embodiments where the stacking transistors are CFETs. For example, the upper epitaxial source/drain regions 162U may be oppositely doped from the lower epitaxial source/drain regions 162L. Alternatively, the conductivity types of the upper epitaxial source/drain regions 162U and the lower epitaxial source/drain regions 162L may be the same. The upper epitaxial source/drain regions 162U may be in-situ doped, and/or may be implanted, with an n-type or p-type dopant. Adjacent upper source/drain regions 162U may remain separated after the epitaxy process or may be merged.

After the epitaxial source/drain regions 162U are formed, a second CESL 170 and a second ILD 172 are formed. The materials and the formation methods may be similar to the materials and the formation methods of first CESL 166 and first ILD 168, respectively, and are not discussed in detail herein. The formation process may include depositing the layers for CESL 170 and ILD 172, and performing a planarization process to remove the excess portion of the corresponding layers. The planarization process may include a laser treatment process. After the planarization process, top surfaces of the second ILD 172, the gate spacers 144, and the masks 186 (if present) or the dummy gates 184 are substantially coplanar (within process variations). Accordingly, the top surfaces of the masks 140 (if present) or the dummy gates 138 are exposed through the second ILD 172. In the illustrated embodiment, the masks 140 remain after the removal process. In other embodiments, the masks 140 are removed such that the top surfaces of the dummy gates 138 are exposed through the second ILD 172.

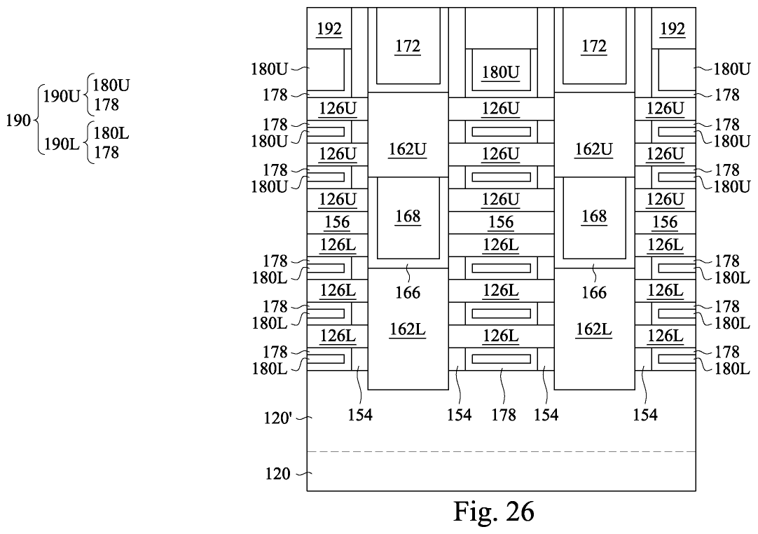

FIG. 26 illustrates a replacement gate process to replace the dummy gate stacks 142 and the dummy nanostructures 124 with gate structures 190. The replacement gate process includes first removing the dummy gate stacks 142 and the remaining portions of the dummy nanostructures 124. The dummy gate stacks 142 are removed in one or more etching processes, so that recesses are defined between the gate spacers 144 and the upper portions of the semiconductor strips 128 are exposed. The remaining portions of the dummy nanostructures 124 are then removed by etching, so that the recesses extend between the semiconductor nanostructures 126. In the etching process, the dummy nanostructures 124 are etched at a faster rate than the semiconductor nanostructures 126, the dielectric isolation layers 156, and the inner spacers 154. The etching may be isotropic. For example, when the dummy nanostructures 124 are formed of silicon-germanium, and the semiconductor nanostructures 126 are formed of silicon, the etch process may include a wet etch process using tetramethylammonium hydroxide (TMAH), ammonium hydroxide (NH₄OH), or the like.

Then, gate dielectrics 178 are deposited in the recesses between the gate spacers 144 and on the exposed semiconductor nanostructures 126. The gate dielectrics 178 are conformally formed on the exposed surfaces of the recesses (the removed gate stacks 142 and the dummy nanostructures 124) including the semiconductor nanostructures 126 and the gate spacers 144. In some embodiments, the gate dielectrics 178 wrap around all (e.g., four) sides of the semiconductor nanostructures 126. Specifically, the gate dielectrics 178 may be formed on the top surfaces of the fins 120′; on the top surfaces, the sidewalls, and the bottom surfaces of the semiconductor nanostructures 126; and on the sidewalls of the gate spacers 144. The gate dielectrics 178 may include an oxide such as silicon oxide or a metal oxide, a silicate such as a metal silicate, combinations thereof, multi-layers thereof, or the like. The gate dielectrics 178 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 178 may include molecular-beam deposition (MBD), ALD, PECVD, and the like followed by a planarization process (e.g., a CMP) to remove portions of the gate dielectrics 178 above the second ILD 172. Although single-layered gate dielectrics 178 are illustrated, the gate dielectrics 178 may include multiple layers, such as an interfacial layer and an overlying high-k dielectric layer.

Lower gate electrodes 180L are formed on the gate dielectrics 178 around the lower semiconductor nanostructures 126L. For example, the lower gate electrodes 180L wrap around the lower semiconductor nanostructures 126L. The lower gate electrodes 180L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 180L may include any number of work function tuning layers, any number of barrier layers, any number of glue layers, and a fill material.

The lower gate electrodes 180L are formed of material(s) that are suitable for the device type of the lower nanostructure-FETs. For example, the lower gate electrodes 180L may include one or more work function tuning layer(s) formed of material(s) that are suitable for the device type of the lower nanostructure-FETs. In some embodiments, the lower gate electrodes 180L include an n-type work function tuning layer, which may be formed of titanium aluminum, titanium aluminum carbide, tantalum aluminum, tantalum carbide, combinations thereof, or the like. In some embodiments, the lower gate electrodes 180L include a p-type work function tuning layer, which may be formed of titanium nitride, tantalum nitride, combinations thereof, or the like. Additionally or alternatively, the lower gate electrodes 180L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 180L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 180L may expose the upper semiconductor nanostructures 126U.

In some embodiments, isolation layers (not explicitly illustrated) may be optionally formed on the lower gate electrodes 180L. The isolation layers act as isolation features between the lower gate electrodes 180L and subsequently formed upper gate electrodes 180U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 126U.

Then, upper gate electrodes 180U are formed on the isolation layers described above (if present) or the lower gate electrodes 180L. The upper gate electrodes 180U are disposed between the upper semiconductor nanostructures 126U. In some embodiments, the upper gate electrodes 180U wrap around the upper semiconductor nanostructures 126U. The upper gate electrodes 180U may be formed of the same candidate materials and candidate processes for forming the lower gate electrodes 180L. The upper gate electrodes 180U are formed of material(s) that are suitable for the device type of the upper nanostructure-FETs. For example, the upper gate electrodes 180U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 180U are illustrated, the upper gate electrodes 180U may include any number of work function tuning layers, any number of barrier layers, any number of glue layers, and a fill material.

Additionally, a removal process is performed to level top surfaces of the upper gate electrodes 180U and the second ILD 172. The removal process for forming the gate dielectrics 178 may be the same removal process as the removal process for forming the upper gate electrodes 180U. In some embodiments, a planarization process such as a CMP process, an etch-back process, combinations thereof, or the like may be utilized. The planarization process may include a laser treatment process. After the planarization process, the top surfaces of the upper gate electrodes 180U, the gate dielectrics 178, the second ILD 172, and the gate spacers 144 are substantially coplanar (within process variations). Each respective pair of a gate dielectric 178 and a gate electrode 180 (including an upper gate electrode 180U and/or a lower gate electrode 180L) may be collectively referred to as a “gate stack” 190 or a “gate structure” 190 (including upper gate structures 190U and lower gate structures 190L). Each gate structure 190 extends along three sides (e.g., a top surface, a sidewall, and a bottom surface) of a channel region of a semiconductor nanostructure 126 (see FIG. 11). The lower gate structures 190L may also extend along sidewalls and/or a top surface of a fin 120′. The gate structures 190 may extend between opposite inner spacers 154, and thus the gate structures 190 may have a width less than a width of the semiconductor nanostructures 126. In some embodiments, some gate structures 190 may have a height that is greater than a height of the inner spacers 154. The gate structures 190 may have curved sidewalls, in some cases.

As also shown in FIG. 26, gate masks 192 are formed over the gate stacks 142. The formation process may include recessing gate stacks 190, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 172. The planarization process may include a laser treatment process.

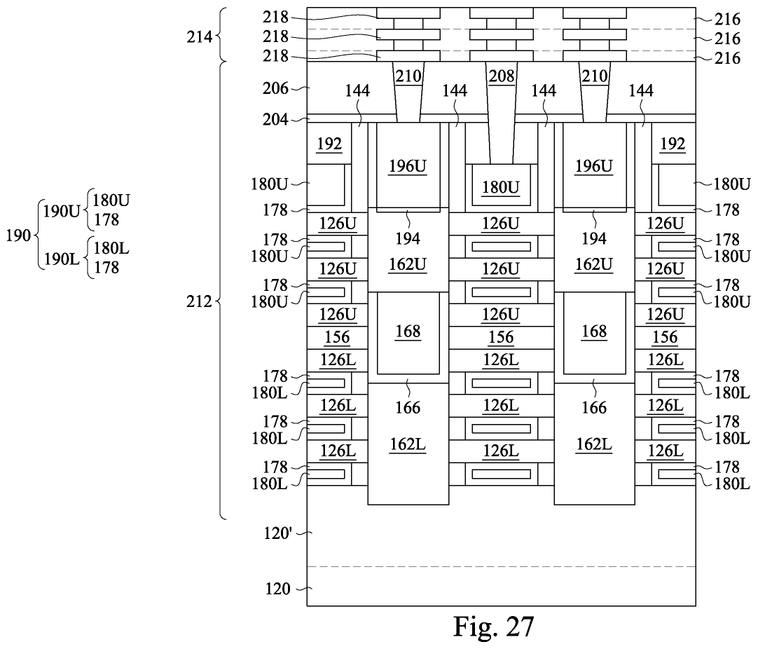

In FIG. 27, metal-semiconductor alloy regions 194 and upper source/drain contacts 196U are formed through the second ILD 172 to electrically couple to the upper epitaxial source/drain regions 162U. As an example to form the upper source/drain contacts 196U, openings are formed through the second ILD 172 and the second CESL 170 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 144 and the second ILD 172. The remaining liner and conductive material form the upper source/drain contacts 196U in the openings. In some embodiments, a planarization process such as a CMP, an etch-back process, combinations thereof, or the like is utilized. The planarization process may include a laser treatment process. After the planarization process, the top surfaces of the gate spacers 144, the second ILD 172, and the upper source/drain contacts 196U are substantially coplanar (within process variations).

Optionally, metal-semiconductor alloy regions 194 are formed at the interfaces between the source/drain regions 162 and the upper source/drain contacts 196U. The metal-semiconductor alloy regions 194 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 194 can be formed before the material(s) of the upper source/drain contacts 196U by depositing a metal in the openings for the upper source/drain contacts 196U and then performing a thermal anneal process. The metal can be any metal capable of reacting with the semiconductor materials (e.g., silicon, silicon-germanium, germanium, etc.) of the source/drain regions 162 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the upper source/drain contacts 196U, such as from surfaces of the metal-semiconductor alloy regions 194. The material(s) of the upper source/drain contacts 196U can then be formed on the metal-semiconductor alloy regions 194.

An ESL 204 and a third ILD 206 are then formed. In some embodiments, the ESL 204 may include a dielectric material having a high etching selectivity from the etching of the third ILD 206, such as aluminum oxide, aluminum nitride, silicon nitride, silicon oxynitride, silicon oxycarbide, or the like. The third ILD 206 may be formed using flowable CVD, ALD, or the like, and the material may include PSG, BSG, BPSG, USG, or the like, which may be deposited by any suitable method, such as CVD, PECVD, or the like.

Subsequently, upper gate contacts 208 and upper source/drain vias 210 are formed to contact the upper gate electrodes 180U and the upper source/drain contacts 196U, respectively. As an example to form the upper gate contacts 208 and the upper source/drain vias 210, openings for the upper gate contacts 208 and the upper source/drain vias 210 are formed through the third ILD 206 and the ESL 204. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 206. The planarization process may include a laser treatment process. The remaining liner and conductive material form the upper gate contacts 208 and the upper source/drain vias 210 in the openings. The upper gate contacts 208 and the upper source/drain vias 210 may be formed in distinct processes, or may be formed in the same process. Although shown as being formed in the same cross-section, it should be appreciated that each of the upper gate contacts 208 and the upper source/drain vias 210 may be formed in different cross-sections, which may avoid shorting of the contacts. The resulting structure may be referred to as a device layer 212, in some cases.

Still referring to FIG. 27, a front-side interconnect structure 214 is formed on the device layer 212. The front-side interconnect structure 214 includes dielectric layers 216 and layers of conductive features 218 in the dielectric layers 216. The dielectric layers 216 may include low-k dielectric layers formed of low-k dielectric materials. The dielectric layers 216 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 216 may also include polymer layers. The conductive features 218 may include conductive lines and vias, which may be formed using damascene processes. Conductive features 218 may include metal lines and metal vias, which includes diffusion barriers and a copper containing material over the diffusion barriers. There may also be aluminum pads over and electrically connected to the metal lines and vias. Additional processing may be performed on the device layer 212, such as the formation of lower source/drain contacts to the lower source/drain regions 162L, the formation of a back-side interconnect structure, or other processing.

Embodiments described herein may achieve advantages. By modifying a material using a laser treatment process as described herein, the modified material may be more easily removed using a planarization process. This can allow for faster planarization and reduced costs. This can also allow for improved uniformity or planarity of the resulting planarized surface. Additionally, performing a laser treatment process as described herein can reduce surface topography and can reduce polishing sensitivity to surface topography. The depth of the modified material may be controlled by controlling the focal point of the laser beam used in the laser treatment process. The laser treatment process can modify a layer throughout its entire thickness, or can modify only an upper portion of the layer. The techniques described herein can reduce under-polishing, over-polishing, or bonding issues resulting from uneven surfaces. Improving planarization process using a laser treatment process as described herein can improve yield and uniformity of overall device processing.

In an embodiment, a method includes forming a first layer over a second layer; performing a laser treatment process on the first layer, wherein the laser treatment process includes directing a laser beam into the first layer, wherein the laser beam modifies the first layer; and after performing the laser treatment process on the first layer, performing a planarization process on the first layer to remove the first layer, wherein the planarization process exposes the second layer. In an embodiment, a focal point of the laser beam is above a top surface of the second layer. In an embodiment, the laser beam has a wavelength in the range of 300 nm to 1500 nm. In an embodiment, the method includes forming a stack of nanostructures over a substrate, wherein the stack of nanostructures includes the second layer, wherein forming the first layer includes depositing the first layer over the stack of nanostructure and on sidewalls of the nanostructures of the stack of nanostructures; and after performing the planarization process, forming a gate structure between neighboring nanostructures of the stack of nanostructures. In an embodiment, the first layer is silicon. In an embodiment, the first layer and the second layer are a same material. In an embodiment, after performing the laser treatment process, the entire first layer is modified. In an embodiment, the laser beam modifies the first layer by heating the first layer. In an embodiment, the planarization process is a chemical mechanical polishing (CMP) process.

In an embodiment, a method includes depositing a first layer over a substrate, wherein the first layer is a first material; and removing an upper portion of the first layer, including scanning a laser beam across a top surface of the first layer, wherein after scanning the laser beam, the upper portion of the first layer has different physical properties than an underlying lower region of the first layer; and polishing the upper portion of the first layer to expose the lower region of the first layer. In an embodiment, a focal point of the laser beam is located a first depth into the first layer, wherein the first depth is less than a first thickness of the first layer. In an embodiment, after scanning the laser beam, a polishing removal rate of the upper region is greater than a polishing removal rate of the lower region. In an embodiment, first material is an oxide. In an embodiment, the laser beam is pulsed during scanning of the laser beam. In an embodiment, after scanning the laser beam, the upper portion of the first layer has a larger volume than the upper portion of the first layer prior to scanning the laser beam. In an embodiment, the method includes depositing a second layer over the substrate, wherein the first layer covers the second layer, wherein polishing the upper portion of the first layer also exposes the second layer.

In an embodiment, a method includes forming a first bonding layer over a first substrate; forming a second bonding layer over a second substrate; bonding the first bonding layer to the second bonding layer using a fusion bonding process; heating the first substrate using a first laser; and removing the first substrate using a first mechanical planarization process. In an embodiment, the first substrate is a silicon wafer. In an embodiment, the method includes forming a dielectric material over the second substrate; heating an upper portion of the dielectric material using a second laser; and removing the upper portion of the dielectric material using a second mechanical planarization process. In an embodiment, the method includes forming a multi-layer stack between the first bonding layer and the first substrate, wherein removing the first substrate exposes the multi-layer stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first layer over a semiconductor substrate;
forming a second layer over the first layer; and
performing a planarization process on the second layer, wherein the planarization process comprises:
performing a heating process on the second layer, wherein the heating process heats the second layer more than the first layer; and
polishing the second layer to remove an upper portion of the second layer.

2. The method of claim 1, wherein the heating process comprises exposing the second layer to laser light.

3. The method of claim 2, wherein the laser light is focused to a first distance below a top surface of the second layer, wherein the first distance is smaller than a thickness of the upper portion of the second layer.

4. The method of claim 1, wherein the second layer is a dielectric material.

5. The method of claim 1, further comprising performing an etching process to recess the second layer.

6. The method of claim 1, wherein, after performing the heating process, a polishing removal rate of the upper portion of the second layer is greater than a polishing removal rate of a lower portion of the second layer, wherein the lower portion of the second layer is between the upper portion of the second layer and the first layer.

7. The method of claim 1, wherein the polishing exposes a top surface of the first layer.

8. The method of claim 1, wherein the polishing fully removes the second layer.

9. A method comprising:
forming a first layer over a second layer;
heating a first region of the first layer;
after heating the first region of the first layer, heating a second region of the first layer that is laterally adjacent to the first region; and
after heating the second region, removing the first region and the second region using a polishing process.

10. The method of claim 9, wherein heating the first region comprises transmitting a laser beam into the first region.

11. The method of claim 10, wherein the laser beam is pulsed.

12. The method of claim 9, wherein the first region and the second region are contiguous.

13. The method of claim 9, further comprising, after heating the second region, heating a third region of the first layer that is between laterally adjacent to the second region.

14. The method of claim 9, wherein a thickness of the first region is less than a thickness of the first layer.

15. A method comprising:
forming a first semiconductor structure over a semiconductor substrate;
performing a first laser treatment on the semiconductor substrate, wherein the first laser treatment comprises focusing a laser to a point within the semiconductor substrate; and
performing a first polishing process on the semiconductor substrate that exposes the first semiconductor structure.

16. The method of claim 15, wherein the first semiconductor structure comprises a multi-layer stack.

17. The method of claim 15, wherein after performing the first laser treatment and before performing the first polishing process, bonding the first semiconductor structure to a second semiconductor structure.

18. The method of claim 15, further comprising:
depositing a dielectric layer over the first semiconductor structure;
performing a second laser treatment on a portion of the dielectric layer; and
removing the portion of the dielectric layer using a second polishing process.

19. The method of claim 15, wherein the first polishing process fully removes the semiconductor substrate.

20. The method of claim 15, wherein the first laser treatment expands the semiconductor substrate.
